(19) United States
(12) Patent Application Publication
(10) Pub. No.: US 2026/0029440 A1
(43) Pub. Date: Jan. 29, 2026

(54) CONTROL DEVICE

(71) Applicant: MITSUBA Corporation, Gunma (JP)

(72) Inventors: TAKUTO TANABE, Gunma (JP); YASUFUMI NOGUCHI, Gunma (JP); HIROAKI OKADA, Gunma (JP); NOBUHIRO SHIMIZU, Gunma (JP); HIKARU SAWADA, Gunma (JP); HIROAKI HIRUMA, Gunma (JP)

(73) Assignee: MITSUBA Corporation, Gunma (JP)

(21) Appl. No.: 19/270,452

(22) Filed: Jul. 15, 2025

(30) Foreign Application Priority Data
Jul. 23, 2024 (JP) 2024-117867

(51) Int. Cl. G01R 15/20; H02G 5/02; H02P 23/00

(52) U.S. Cl. CPC G01R 15/207; H02G 5/02; H02P 23/00

(57) ABSTRACT

A control device includes an energization busbar, a substrate, a magnetic detection type current sensor, a case, and a base member. A controller is mounted on the substrate. The current sensor is mounted at a position close to the busbar on the substrate and detects a magnetic field caused by current flowing through the busbar. The case accommodates the substrate and the busbar. The case is fixed to the base member. The busbar is partially embedded and fixed in the case. The substrate is directly fixed to the base member.

### CROSS-REFERENCE TO RELATED APPLICATION

This application claims the priority benefits of Japanese application no. 2024-117867, filed on Jul. 23, 2024. The entirety of the above-mentioned patent application is hereby incorporated by reference herein and made a part of this specification.

### BACKGROUND

### Technical Field

The disclosure relates to a control device.

### Related Art

As a control device for motor driving, one that converts DC power supplied from a battery to AC power and drives a motor with the converted AC power is known. In such control devices, it is necessary to accurately detect the energization current value to the motor and the input current value from the battery for control of the energization current to the motor and perform fail-stop in the case of overcurrent energization. As a countermeasure for this, one in which a current sensor is installed in the peripheral area of an energization busbar (electrode) connected to a power control circuit is known.

The current sensor has a magnetic core and a Hall element (magnetic detection element) arranged in the peripheral area of an energization busbar connected to a power control circuit. This current sensor has a mechanism that amplifies a magnetic field generated due to current flowing through the energization busbar by the magnetic core, and detects the magnetic field amplified by the magnetic core by the Hall element.

However, a current sensor having a structure in which a magnetic core and a Hall element are arranged in the peripheral area of an energization busbar causes the entire apparatus to become larger and manufacturing costs to increase by providing the magnetic core.

As a countermeasure for this, in recent years, coreless current detection that detects a magnetic field generated in the peripheral area of an electrode only by a magnetic detection element such as a Hall element without providing a magnetic core has been studied (for example, see Patent Document 1).

### CITATION LIST

### Patent Document

[Patent Document 1] Japanese Patent Application Laid-Open Publication No. 2013-195381

However, since the coreless current detection described in Patent Document 1 directly detects magnetic flux, the detected current value greatly fluctuates due to slight changes in the separation distance between the magnetic detection element and the energization busbar. Thus, in the case of assembling the current sensor (magnetic detection element) and busbar to the case of the control device, it is desired to reduce these assembly errors and make the separation distance (air gap) between the current sensor and busbar as small as possible.

Moreover, even in the case of some variation in the separation distance between the current sensor and busbar, normally, the influence of the variation on detection results can be eliminated by performing adjustment (calibration) of the current value conversion program after assembling the current sensor and busbar to the case. However, in the case of the variation in separation distance between the current sensor and busbar being too large, it becomes difficult to properly perform initial setting by adjustment of the current value conversion program.

Thus, the disclosure provides a control device that improves assembly accuracy of a current sensor and busbar, and improves detection accuracy of current values flowing through the busbar.

### SUMMARY

A control device includes an energization busbar; a substrate on which a controller is mounted; a magnetic detection type current sensor that is mounted at a position close to the busbar on the substrate and that detects a magnetic field caused by current flowing through the busbar; a case that accommodates the substrate and the busbar; and a base member to which the case is fixed. The busbar is partially embedded and fixed in the case, and the substrate is directly fixed to the base member.

### BRIEF DESCRIPTION OF THE DRAWINGS

FIG. 1 is a perspective view showing a control device according to an embodiment of the disclosure.

FIG. 2 is an exploded perspective view of a control device according to an embodiment of the disclosure.

FIG. 3 is a perspective view of a control device according to an embodiment of the disclosure with a case removed.

FIG. 4 is a plan view of a control device according to an embodiment of the disclosure with a substrate removed from FIG. 3.

FIG. 5 is a perspective view of a control device according to an embodiment of the disclosure with a case and a substrate removed.

FIG. 6 is a cross-sectional view of a control device according to an embodiment of the disclosure taken along line VI-VI of FIG. 4.

### DESCRIPTION OF THE EMBODIMENTS

In a first aspect of the disclosure, a control device includes an energization busbar; a substrate on which a controller is mounted; a magnetic detection type current sensor that is mounted at a position close to the busbar on the substrate and that detects a magnetic field caused by current flowing through the busbar; a case that accommodates the substrate and the busbar; and a base member to which the case is fixed. The busbar is partially embedded and fixed in the case, and the substrate is directly fixed to the base member.

By configuring in this way, the busbar is partially embedded in the case and is integrated with the case. As a result, in response to the case being fixed to the base member, the busbar integrated with the case is assembled to the base member with high accuracy. Moreover, the substrate is assembled to the base member with high accuracy by being directly fixed to the base member. Thus, since the busbar and substrate are respectively assembled with high accuracy with the common base member as a reference, it becomes possible to reduce variation in separation distance between the current sensor and busbar. Thus, assembly accuracy of the current sensor and busbar can be improved, and detection accuracy of current values flowing through the busbar can be improved.

Moreover, by the substrate being directly fixed to the base member, support rigidity of the substrate increases, making the substrate less likely to vibrate. Thus, fluctuation in separation distance between the busbar and sensor due to vibration of the substrate can be suppressed.

In a second aspect of the disclosure, in the control device of the first aspect, the case includes a case main body that has an opening part at a portion facing the substrate and that covers an installation part of the current sensor on the substrate and an outer side of the busbar; and a cover part that is detachably mounted to the case main body so as to close the opening part.

By configuring in this way, after installing the current sensor and busbar, an adjustment device for a current value conversion program may be connected to the substrate in a state where the opening part of the case main body is open. Thus, it becomes possible to adjust the current value conversion program stored in an IC or the like on the substrate to an appropriate value according to the gap between the current sensor and busbar by the adjustment device connected to the substrate. Thus, after adjusting the current value conversion program, the adjustment device is removed from the substrate and the opening part of the case main body is closed.

Thus, in the case of adopting this configuration, it becomes possible to suppress deterioration in detection accuracy of the current sensor caused by variation in separation distance between the current sensor and busbar.

In a third aspect of the disclosure, in the control device of the first aspect or the second aspect, the current sensor is provided to oppose the busbar, and a portion of the busbar embedded and fixed in the case is arranged at a position close to the current sensor.

By configuring in this way, a vicinity part of the embedded fixing part of the busbar that is supported by the case with high rigidity becomes a detection target part of magnetic field by the current sensor. Thus, separation distance between the detection target part of the busbar and the current sensor can be easily made constant.

In a fourth aspect of the disclosure, in the control device of any one of the first aspect to the third aspect, the base member includes a pillar part that protrudes in a direction of the substrate and to which the substrate is fixed, a fixing part to which the pillar part is fixed is provided at an end part of the substrate in an extending direction, and the current sensor is arranged in a vicinity of the fixing part.

By configuring in this way, an end part in an extending direction of the substrate is supported by the base member via the pillar part. In the case of vibration input from outside to the substrate, amplitude of a central region tends to become large. In contrast, the fixing part at the end part in the extending direction of the substrate is easily suppressed from vibration by the pillar part, and does not vibrate with large amplitude even in the case of vibration input from outside. Thus, the current sensor arranged in a vicinity of the fixing part at the end part in the extending direction of the substrate does not vibrate significantly in response to input even in the case of vibration input from outside. Thus, in the case of adopting this configuration, it becomes possible to further suppress fluctuation in separation distance between the busbar and current sensor.

According to the disclosure, it is possible to provide a control device that improves assembly accuracy of the current sensor and busbar and improves detection accuracy of a current value flowing through the busbar.

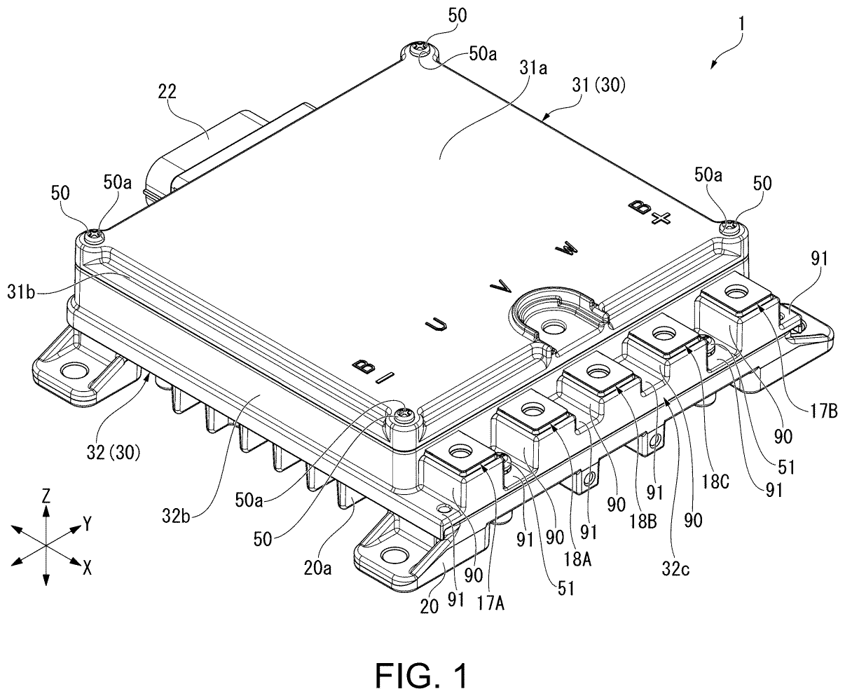

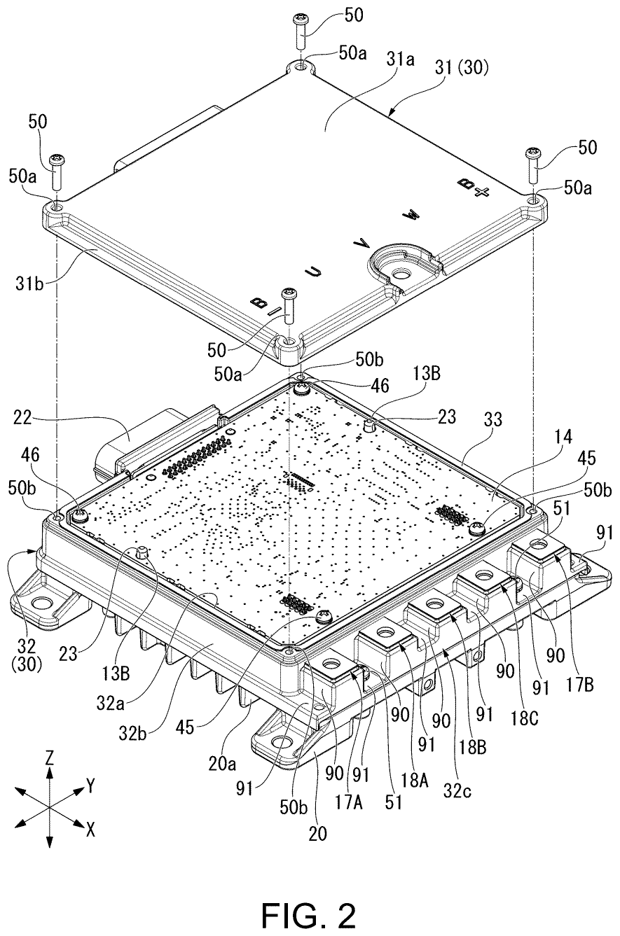

Next, an embodiment of the disclosure will be described based on the drawings. FIG. 1 is a perspective view of a control device 1. FIG. 2 is an exploded perspective view of the control device 1. The control device 1 includes an inverter function that converts DC power supplied from a battery (not shown) to AC power and drives a motor (AC motor) (not shown) with the converted AC power.

As shown in FIG. 1 and FIG. 2, the control device 1 includes a case 30, a metal base member 20 formed by aluminum die casting or the like, a second substrate 14 (substrate) on which a controller is mounted, and multiple busbars (battery side busbars 17A, 17B, motor side busbars 18A, 18B, 18C). The base member 20 is a member to which the case 30 accommodating multiple devices is mounted. Multiple fins 20a for heat dissipation are protruded on an outer side surface of the base member 20.

In the following, for convenience of description, the side of the base member 20 on which multiple fins 20a are protruded is referred to as “lower”, and the opposite side is referred to as “upper”.

The case 30 includes a case main body 32 having a rectangular opening part 32a, and a cover part 31 detachably mounted to an upper surface of the case main body 32 so as to close the opening part 32a. A seal member 33 that seals a gap between the cover part 31 and the case main body 32 is provided between the cover part 31 and the opening part 32a. Main parts of the case main body 32 and the cover part 31 are formed by resin material.

The cover part 31 is detachably mounted to the case main body 32. The cover part 31 has an upper surface part 31a directed upward, and side surface parts 31b directed in directions (four directions) orthogonal to the upper surface part 31a. The upper surface part 31a has insertion holes 50a through which bolts 50 are respectively inserted formed at four corners of the upper surface part 31a when viewed from above. The side surface parts 31b are formed with substantially right-angled steps.

The case main body 32 includes a main body block part 32b having a rectangular frame shape in top view, and a busbar support part 32c continuously connected to one side surface of the main body block part 32b. The main body block part 32b has an opening part 32a that opens upward. The main body block part 32b has insertion holes 50b through which the bolts 50 are respectively inserted formed at four corners of the main body block part 32b in top view.

A shaft part of each bolt 50 is inserted through corresponding insertion holes 50a, 50b at four corners of the cover part 31 and the case main body 32, and is tightened into the case main body 32 from the upper side of the cover part 31. The cover part 31 is thereby fastened and fixed to the case main body 32.

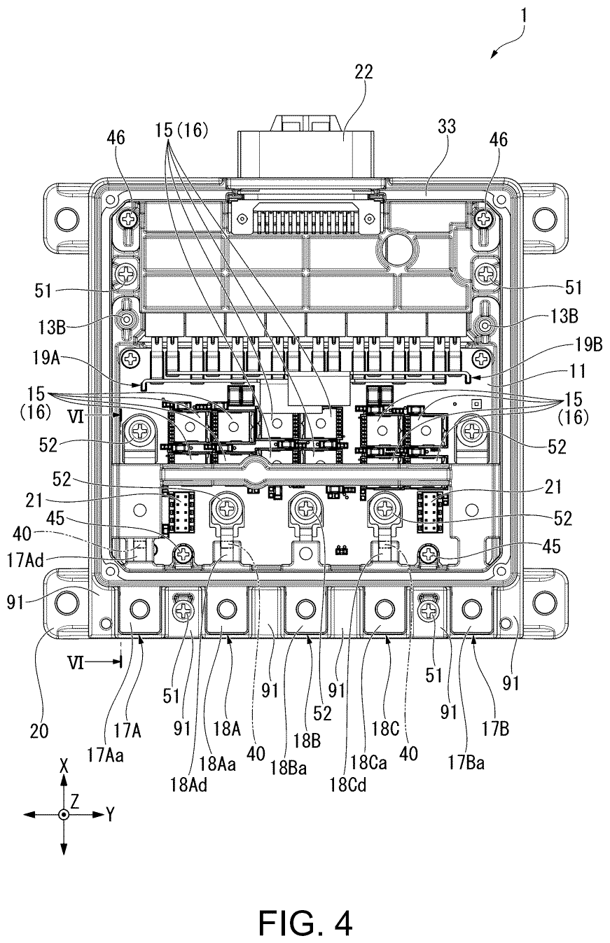

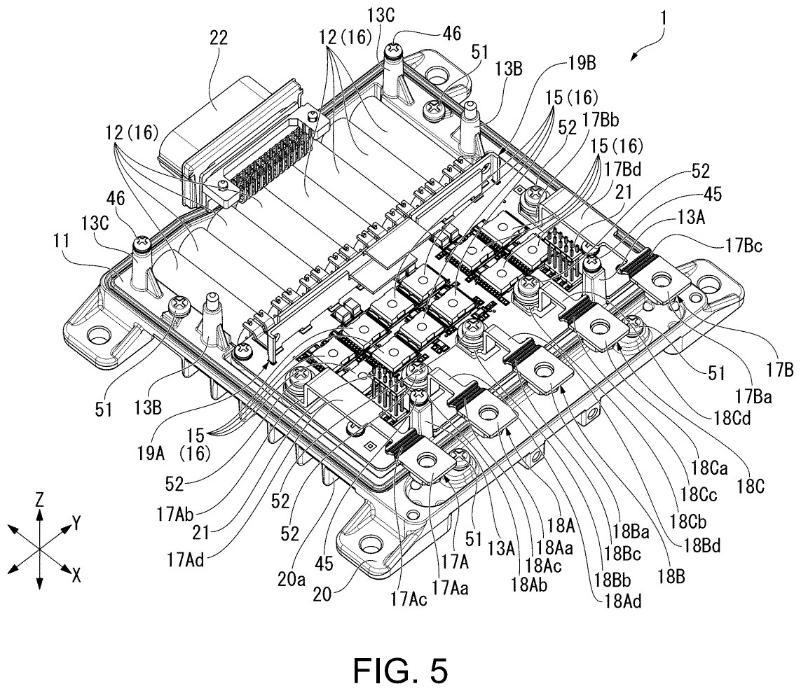

Each one end part of multiple busbars (battery side busbars 17A, 17B, motor side busbars 18A, 18B, 18C) is supported by the busbar support part 32c. The busbar support part 32c supports each lower surface of terminal fixing parts (17Aa, 17Ba, 18Aa, 18Ba, 18Ca (see FIG. 4 and FIG. 5)) to be described later in the multiple busbars. In the busbar support part 32c, portions that support each terminal fixing part 17Aa, 17Ba, 18Aa, 18Ba, 18Ca are raised upward. These portions raised upward are hereinafter referred to as “raised parts 90”. The multiple raised parts 90 are arranged at regular intervals, and recess parts 91 are provided between adjacent raised parts 90.

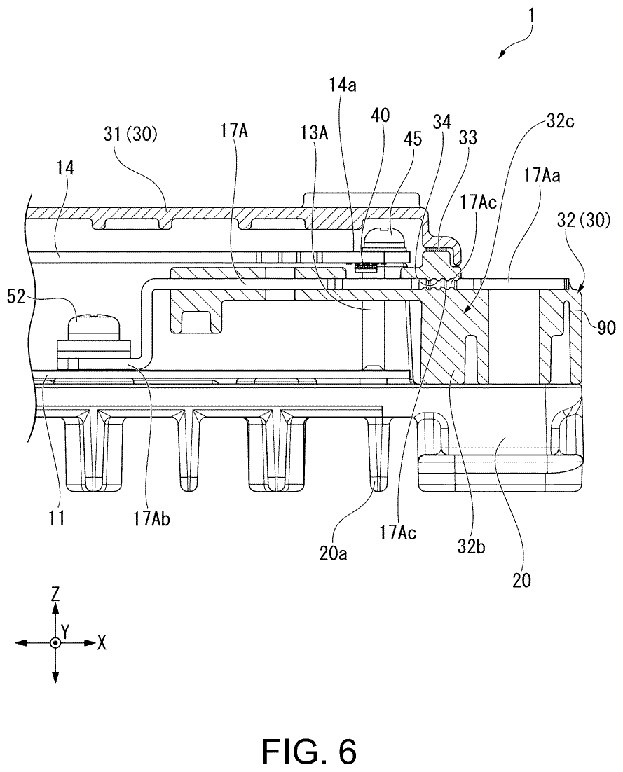

In parts of a peripheral wall of the main body block part 32b adjacent to each raised part 90, embedded parts 34 are provided where each part of multiple busbars (battery side busbars 17A, 17B, motor side busbars 18A, 18B, 18C) is embedded and fixed by molding (see FIG. 6). Each busbar penetrates the peripheral wall of the main body block part 32b at an embedded part 34.

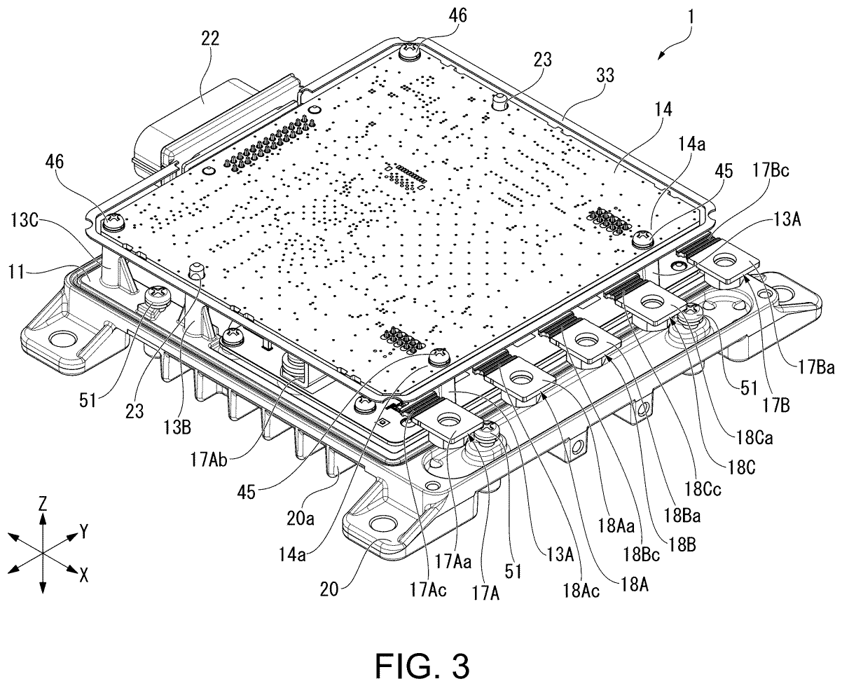

FIG. 3 is a perspective view of the control device 1 with the case 30 removed. FIG. 4 is a plan view of the control device 1 with the cover part 31 removed. FIG. 5 is a perspective view of the control device 1 with the case 30 and the second substrate 14 removed. As shown in FIG. 3, FIG. 4, and FIG. 5, a first substrate 11 and multiple electrolytic capacitors 12 (see FIG. 5) are arranged on an upper surface side of the base member 20. Moreover, multiple pillar parts 13A, 13B, 13C that protrude toward the upper side are provided on the base member 20. A second substrate 14 is supported on upper parts of the multiple pillar parts 13A, 13B, 13C. The second substrate 14 is arranged on the upper side of the first substrate 11 and the multiple electrolytic capacitors 12 so as to be substantially parallel to the first substrate 11. As shown in FIG. 3, the first substrate 11 is arranged near one side of an upper surface of the base member 20 having a substantially rectangular shape in plan view, and the multiple electrolytic capacitors 12 are arranged near other side of the upper surface of the base member 20.

The case main body 32 (case 30) is fixed to the base member 20 by fixing screws 45 at two locations separated in the Y direction of the busbar support part 32c, and is fixed to the base member 20 by fixing screws 51 at two locations separated in the Y direction of the main body block part 32b, as shown in FIG. 4.

The first substrate 11 is a printed circuit board (PWB) on which multiple electronic components including switching elements 15 are mounted. Multiple switching elements 15 are combined to constitute a main part of a power control circuit 16 together with the electrolytic capacitor 12. The power control circuit 16 performs ON/OFF operation by control of the switching elements 15 by a control part (not shown), thereby converting DC power of a battery to three-phase AC power.

Connected to the power control circuit 16 are a pair of battery side busbars 17A, 17B which are electrodes for energization on the battery side, and three motor side busbars 18A, 18B, 18C which are electrodes for energization on the motor side. The pair of battery side busbars 17A, 17B are connectable to a negative pole and a positive pole of a battery via connection cables (not shown), respectively. The three motor side busbars 18A, 18B, 18C are connectable to U-phase, V-phase, and W-phase power supply parts of a motor via connection cables (not shown), respectively.

The electrolytic capacitors 12 arranged near other side of the upper surface of the base member 20 are formed in a substantially cylindrical shape. These multiple electrolytic capacitors 12 are arranged in parallel in a direction orthogonal to the longitudinal direction (axial direction). The multiple electrolytic capacitors 12 are connected to circuits on the first substrate 11 via connection busbars 19A, 19B that are surface-mounted on the first substrate 11.

Hereinafter, the direction along the longitudinal direction (axial direction) of the electrolytic capacitors 12 is referred to as the X direction. Moreover, the direction in which the electrolytic capacitors 12 are arranged in parallel is referred to as the Y direction, and the direction orthogonal to the X direction and Y direction is referred to as the Z direction. Arrows indicating the X direction, Y direction, and Z direction are marked at appropriate places in the drawings.

FIG. 6 is a cross-sectional view of the control device 1 taken along line VI-VI in FIG. 4. On the upper surface of the first substrate 11, a negative side circuit terminal and a positive side circuit terminal (not shown) that are connected to the negative side battery side busbar 17A and the positive side battery side busbar 17B, respectively, are mounted.

The battery side busbars 17A, 17B are both formed by long plate-shaped conductive metal plates. One end side in the longitudinal direction of each battery side busbar 17A, 17B penetrates the peripheral wall on one end side in the X direction of the main body block part 32b and is supported on the corresponding raised part 90 of the busbar support part 32c. This portion serves as terminal fixing parts 17Aa, 17Ba. Moreover, the other end side in the longitudinal direction of each battery side busbar 17A, 17B serves as circuit fixing parts 17Ab, 17Bb that are connected to the above-mentioned negative side circuit terminal and positive side circuit terminal on the first substrate 11. Moreover, the portions that are arranged on the inner side in the X direction of the terminal fixing parts 17Aa, 17Ba and penetrate the main body block part 32b serve as wave-shaped parts 17Ac, 17Bc that are embedded and fixed in the embedded part 34 of the main body block part 32b (case 30). The wave-shaped parts 17Ac, 17Bc have multiple grooves along the Y direction formed on both upper and lower surfaces (surfaces on both sides in the Z direction), and wave-shaped continuous irregularities formed on both side edges in the Y direction.

On the inner side in the X direction of the wave-shaped parts 17Ac, 17Bc in each battery side busbar 17A, 17B, high-level extension parts 17Ad, 17Bd extend further horizontally from the wave-shaped parts 17Ac, 17Bc. The end parts in the extension direction of the high-level extension parts 17Ad, 17Bd are bent downward and connected to the circuit fixing parts 17Ab, 17Bb. The high-level extension parts 17Ad, 17Bd are arranged at a higher position than the circuit fixing parts 17Ab, 17Bb. The high-level extension parts 17Ad, 17Bd are arranged at a height position where their upper surfaces are close to the lower surface of the second substrate 14.

The battery side busbars 17A, 17B have their terminal fixing parts 17Aa, 17Ba and wave-shaped parts 17Ac, 17Bc fixed to the case main body 32 such that their longitudinal direction is along the X direction. The wave-shaped parts 17Ac, 17Bc are embedded and fixed to the case main body 32 by the embedded part 34. The circuit fixing parts 17Ab, 17Bb of the battery side busbars 17A, 17B are fixed to the base member 20 by bolts 52 that penetrate the first substrate 11 in the up-down direction.

Moreover, on the upper surface of the first substrate 11, three output side circuit terminals (not shown) for U-phase, V-phase, and W-phase, which are power output parts to the motor, are mounted. These output side circuit terminals are arranged in the central region in the Y direction of the first substrate 11, spaced approximately equally in the Y direction. Motor side busbars 18A, 18B, 18C, which are electrodes for energization, are respectively connected to each of the output side circuit terminals.

The motor side busbars 18A, 18B, 18C are formed by long plate-shaped conductive metal plates, similar to the battery side busbars 17A, 17B. One end side in the longitudinal direction of the motor side busbars 18A, 18B, 18C penetrates the peripheral wall on one end side in the X direction of the main body block part 32b and is supported on the corresponding raised part 90 of the busbar support part 32c. This portion serves as terminal fixing parts 18Aa, 18Ba, 18Ca. Moreover, the other end side in the longitudinal direction of each motor side busbar 18A, 18B, 18C serves as circuit fixing parts 18Ab, 18Bb, 18Cb that are connected to the respective output side circuit terminals on the first substrate 11. Moreover, the portions arranged on the inner side in the X direction of the terminal fixing parts 18Aa, 18Ba, 18Ca and penetrating the main body block part 32b serve as wave-shaped parts 18Ac, 18Bc, 18Cc that are embedded and fixed to the main body block part 32b (case 30). The wave-shaped parts 18Ac, 18Bc, 18Cc have multiple grooves along the Y direction formed on both upper and lower surfaces (surfaces on both sides in the Z direction), and wave-shaped continuous irregularities are formed on both side edges in the Y direction.

On the inner side in the X direction of the wave-shaped parts 18Ac, 18Bc, 18Cc in each motor side busbar 18A, 18B, 18C, high-level extension parts 18Ad, 18Bd, 18Cd extend further horizontally from the wave-shaped parts 18Ac, 18Bc, 18Cc. The end parts in the extension direction of these high-level extension parts 18Ad, 18Bd, 18Cd are bent downward and connected to the circuit fixing parts 18Ab, 18Bb, 18Cb. The high-level extension parts 18Ad, 18Bd, 18Cd are arranged at a higher position than the circuit fixing parts 18Ab, 18Bb, 18Cb. The high-level extension parts 18Ad, 18Bd, 18Cd are arranged at a height position where their upper surfaces are close to the lower surface of the second substrate 14.

The motor side busbars 18A, 18B, 18C have their terminal fixing parts 18Aa, 18Ba, 18Ca and wave-shaped parts 18Ac, 18Bc, 18Cc fixed to the case main body 32 such that the longitudinal direction is along the X direction. The wave-shaped parts 18Ac, 18Bc, 18Cc are embedded and fixed to the case main body 32 by the embedded part 34. The circuit fixing parts 18Ab, 18Bb, 18Cb of the motor side busbars 18A, 18B, 18C are fixed to the base member 20 by the bolts 52 that penetrate the first substrate 11 in the up-down direction.

The three motor side busbars 18A, 18B, 18C are arranged side by side in a row along the Y direction. The three motor side busbars 18A, 18B, 18C are arranged at equal intervals in the Y direction. One battery side busbar 17A is arranged adjacent to the outer lateral side of one end side in the arrangement direction of the three motor side busbars 18A, 18B, 18C, and the other battery side busbar 17B is arranged adjacent to the outer lateral side of the other end side in the arrangement direction of the three motor side busbars 18A, 18B, 18C. Thus, the pair of battery side busbars 17A, 17B and the three motor side busbars 18A, 18B, 18C are arranged side by side in a row along the Y direction.

The terminal fixing parts 17Aa, 17Ba, 18Aa, 18Ba, 18Ca of the battery side busbars 17A, 17B and the motor side busbars 18A, 18B, 18C are arranged in a row along the Y direction at one end side in the X direction.

The second substrate 14 is a printed circuit board (PWB) on which electronic components are mounted. The circuit printed on the second substrate 14 is connected to the circuit on the first substrate 11 via an inter-substrate connector 21 (see FIG. 5). Moreover, a signal connector 22 is held between the case main body 32 and the cover part 31. Multiple signal terminals protruding from the signal connector 22 are also connected to the circuit on the second substrate 14.

The second substrate 14 is formed in a substantially rectangular shape as shown in FIG. 2 and FIG. 3. One end edge of the second substrate 14 in the X direction is fixed to a pair of pillar parts 13A protruding from the base member 20. The pair of pillar parts 13A are arranged separated in the Y direction, and each penetrates the second substrate 14 in the up-down direction. On the upper surface of each pillar part 13A, one end edge of the second substrate 14 in the X direction is placed. One end edge of the second substrate 14 in the X direction is fastened and fixed to the upper end part of each pillar part 13A by fixing screws 45 in that state.

The other side of the second substrate 14 in the X direction is fixed to two pairs of pillar parts 13B, 13C protruding from the base member 20. The other end edge of the second substrate 14 in the X direction is placed on the upper surfaces of a pair of pillar parts 13C, and is fixed to the upper end part of each pillar part 13C by fixing screws 46 in that state. Moreover, another pair of pillar parts 13B penetrate the second substrate 14 in the up-down direction, and are fitted into fitting holes 23 of the second substrate 14 in that state.

Three Hall ICs 40 that incorporate Hall elements, which are magnetic detection elements, are mounted on the lower surface of the second substrate 14 near one side in the X direction (end part in the extending direction).

One Hall IC 40 is arranged below the second substrate 14 so as to oppose the high-level extension part 17Ad of one battery side busbar 17A (for example, the negative pole side busbar). This Hall IC 40 opposes the upper surface of the high-level extension part 17Ad of the battery side busbar 17A with a minute gap sandwiched therebetween. This Hall IC 40 detects the magnetic force generated due to the current in the case of DC current of the battery flowing through the battery side busbar 17A. The detection circuit determines the current value flowing through the battery side busbar 17A based on the detection magnetic force.

Another one Hall IC 40 is arranged below the second substrate 14 so as to oppose the high-level extension part 18Ad of the motor side busbar 18A on one end side in the arrangement direction. This Hall IC 40 opposes the upper surface of the high-level extension part 18Ad of the motor side busbar 18A with a minute gap sandwiched therebetween. The Hall IC 40 detects the magnetic force generated due to the current in the case of AC current flowing from the power control circuit 16 to the motor side busbar 18A. The detection circuit determines the current value flowing through the motor side busbar 18A based on the detection magnetic force.

Moreover, the remaining one Hall IC 40 is arranged below the second substrate 14 so as to oppose the high-level extension part 18Cd of the motor side busbar 18C on the other end side in the arrangement direction. This Hall IC 40 opposes the upper surface of the high-level extension part 18Cd of the motor side busbar 18C with a minute gap sandwiched therebetween. The Hall IC 40 detects the magnetic force generated due to the current in the case of AC current flowing from the power control circuit 16 to the motor side busbar 18C. The detection circuit determines the current value flowing through the motor side busbar 18C based on the detection magnetic force.

In the embodiment, a Hall IC 40 for detecting the current flowing through the central motor side busbar 18B is not provided. The current value of the current flowing through the central motor side busbar 18B is determined by calculation based on the detection values of the currents flowing through the motor side busbars 18A, 18C on both sides.

Moreover, in the embodiment, the Hall IC 40 mounted on the lower surface of the second substrate 14 constitutes a magnetic detection type current sensor.

In the embodiment, the Hall IC 40 in which the Hall element and amplification circuit are packaged is configured, but the Hall element and amplification circuit may be configured separately. In this case, at least the Hall element is arranged close to the corresponding busbar. Moreover, the Hall IC 40 is not limited to the Hall element. The Hall IC 40 may be another element as long as it is an element capable of detecting the magnetic field caused by the current flowing through the corresponding busbar.

Here, the installation parts of the above three Hall ICs 40 are all arranged in the vicinity of a fixing part 14a by the pillar part 13A among the end edges (end parts in the extending direction) of the second substrate 14. In the case of the embodiment, the fixing part 14a at the end edge of the second substrate 14 is constituted by a clamp portion formed by the upper end surface of each pillar part 13A and the head part of the fixing screw 45. Moreover, the three Hall ICs 40 arranged at the end edge of the second substrate 14 are arranged side by side in a row along the end edge (along the Y direction).

The arrangement relationship of each pillar part 13A with respect to the busbar is as follows.

One pillar part 13A is arranged at an approximately intermediate position between the motor side busbar 18A on one end side in the arrangement direction and one battery side busbar 17A adjacent to the motor side busbar 18A. Thus, the Hall IC 40 arranged to oppose the upper surface of the high-level extension part 18Ad of the motor side busbar 18A and the Hall IC 40 arranged to oppose the upper surface of the high-level extension part 17Ad of the battery side busbar 17A have approximately equal distances from the fixing part 14a by the one pillar part 13A.

The other pillar part 13A is arranged at an approximately intermediate position between the motor side busbar 18C on the other end side in the arrangement direction and the other battery side busbar 17B adjacent to the motor side busbar 18C. The Hall IC 40 arranged to oppose the upper surface of the high-level extension part 18Cd of the motor side busbar 18C and the Hall IC 40 arranged to oppose the upper surface of the high-level extension part 18Ad of the motor side busbar 18A have approximately equal distances from the fixing part 14a by the other pillar part 13A.

These distances (distances from each fixing part 14a to the nearby Hall IC 40) are set to distances such that the vibration amplitude of the installation part of the Hall IC 40 falls within the allowable range in response to vibration input from the outside. Here, the “allowable range” means that the detection value of the magnetic field (current) by the Hall IC 40 falls within an acceptable error range. Moreover, the input vibration from the outside assumes, in the embodiment, the input vibration in the case of mounting the control device 1 on a vehicle.

### Effects of Embodiment

As described above, in the control device 1 of the embodiment, the second substrate 14 (substrate) and the battery side busbars 17A, 17B and the motor side busbars 18A, 18B, 18C (busbars) are accommodated in the case 30, and the case 30 is fixed to the base member 20. Moreover, parts of the battery side busbars 17A, 17B and the motor side busbars 18A, 18B, 18C (busbars) are embedded and fixed in the case 30, and the second substrate 14 (substrate) is directly fixed to the base member 20.

In this configuration, the wave-shaped parts 17Ac, 17Bc, 18Ac, 18Bc, 18Cc in the battery side busbars 17A, 17B and the motor side busbars 18A, 18B, 18C (busbars) are embedded in the embedded part 34 in the case main body 32 (case 30). The battery side busbars 17A, 17B and the motor side busbars 18A, 18B, 18C (busbars) are integrated with the case main body 32 (case 30) by the resin of the embedded part 34 flowing into multiple grooves along the Y direction formed in the wave-shaped parts 17Ac, 17Bc, 18Ac, 18Bc, 18Cc during molding. As a result, in the case of the case main body 32 being fixed to the base member 20, the busbars integrated with the case main body 32 are assembled to the base member 20 with high accuracy.

Moreover, the second substrate 14 (substrate) is directly fixed to the two pairs of pillar parts 13A, 13C protruding from the base member 20. The upper end parts of each pillar part 13A, 13C are assembled to the base member 20 with high accuracy by being fastened and fixed by the fixing screws 45, 46. Thus, the battery side busbars 17A, 17B and the motor side busbars 18A, 18B, 18C (busbars) and the second substrate 14 are each assembled with high accuracy with the common base member 20 as a reference. Accordingly, variation in the separation distance between the battery side busbars 17A, 17B and the motor side busbars 18A, 18B, 18C (busbars) and the corresponding Hall ICs 40 (current sensors) may be reduced. Thus, the assembly accuracy of the Hall ICs 40 and the busbars can be improved, and the detection accuracy of the current values flowing through the busbars can be improved.

Moreover, by the second substrate 14 being directly fixed to the pillar parts 13A, 13C of the base member 20, the support rigidity of the second substrate 14 increases, and the second substrate 14 becomes difficult to vibrate. Thus, fluctuation in the separation distance between the battery side busbars 17A, 17B and the motor side busbars 18A, 18B, 18C (busbars) and the corresponding Hall ICs 40 due to vibration of the second substrate 14 can be suppressed.

Thus, in the case of adopting the control device 1 of the embodiment, the detection accuracy of current flowing through the battery side busbars 17A, 17B and the motor side busbars 18A, 18B, 18C (busbars) can be stably enhanced. Accordingly, it becomes possible to contribute to Goal 7 “Ensure access to affordable, reliable, sustainable and modern energy for all” and Goal 8 “Promote sustained, inclusive and sustainable economic growth, full and productive employment and decent work for all” of the Sustainable Development Goals (SDGs) led by the United Nations.

The control device 1 of the embodiment includes a case 30 that includes a case main body 32 having an opening part 32a at a portion facing the second substrate 14, and a cover part 31 detachably mounted to the case main body 32. Thus, after installing the Hall ICs 40 and the battery side busbars 17A, 17B and the motor side busbars 18A, 18B, 18C (busbars), an adjustment device for the current value conversion program may be connected to the second substrate 14 in a state where the opening part 32a of the case main body 32 is open. Thus, the current value conversion program stored in the ICs and the like on the second substrate 14 may be adjusted to appropriate values according to the gaps between the battery side busbars 17A, 17B and the motor side busbars 18A, 18B, 18C (busbars) and the corresponding Hall ICs 40 by the adjustment device connected to the second substrate 14. After adjusting the current value conversion program in this way, the adjustment device is removed from the second substrate 14 and the opening part 32a of the case main body 32 is closed by the cover part 31.

Thus, in the case of adopting this configuration, there is no need to perform work such as tightening and fixing the case 30 to the base member 20 after adjusting the current value conversion program. Thus, it becomes possible to suppress deterioration in detection accuracy of the Hall ICs 40 caused by variation in the separation distance between the battery side busbars 17A, 17B and the motor side busbars 18A, 18B, 18C (busbars) and the corresponding Hall ICs 40.

In the control device 1 of the embodiment, the Hall ICs 40 are provided to respectively oppose the battery side busbars 17A, 17B and the motor side busbars 18A, 18B, 18C (busbars), and the wave-shaped parts 17Ac, 17Bc, 18Ac, 18Bc, 18Cc, which are portions of each busbar directly embedded in the case 30, are arranged at positions close to the Hall ICs 40. Thus, the high-level extension parts 17Ad, 17Bd, 18Ad, 18Bd, 18Cd connected to the wave-shaped parts 17Ac, 17Bc, 18Ac, 18Bc, 18Cc of each busbar supported by the case 30 with high rigidity become the detection target parts for magnetic field detection by the Hall ICs 40. Thus, the separation distance between the detection target parts of the busbars and the Hall ICs 40 may be easily kept constant.

In the control device 1 of the embodiment, the Hall ICs 40 are arranged in the vicinity of the fixing parts 14a by the pillar parts 13A at the end parts in the extending direction of the second substrate 14. Thus, the end parts in the extending direction of the second substrate 14 are supported by the base member 20 via the pillar parts 13A. In the second substrate 14, the amplitude of the central region tends to increase in response to vibration input from the outside. In contrast, the fixing parts 14a at the end edges in the extending direction of the second substrate 14 are easily suppressed from vibration by the pillar parts 13A, and do not vibrate with large amplitude even in the case of vibration input from the outside. Thus, the Hall ICs 40 arranged in the vicinity of the fixing parts 14a at the end edges in the extending direction of the second substrate 14 do not vibrate significantly in response to input even in the case of vibration input from the outside. Thus, in the case of adopting this configuration, it becomes possible to further suppress fluctuation in the separation distance between the battery side busbars 17A, 17B and the motor side busbars 18A, 18B, 18C (busbars) and the corresponding Hall ICs 40.

The disclosure is not limited to the above embodiment, and various design changes are possible within the scope that does not depart from the gist thereof. For example, in the above embodiment, the Hall ICs 40 are respectively arranged at positions opposing the two motor side busbars 18A, 18C, but the Hall ICs 40 may be arranged at positions opposing each of the three motor side busbars 18A, 18B, 18C.

Moreover, in the above embodiment, the power control circuit 16 is configured by the mounted components on the first substrate 11 and the electrolytic capacitor 12, but a part of the power control circuit 16 may be provided on the second substrate 14.

Moreover, in the above embodiment, the battery side busbars 17A, 17B and the motor side busbars 18A, 18B, 18C (busbars) are all configured by long plate-shaped conductive metal plates, but the busbars are not limited to long plate-shaped conductive metal plates. The busbars may be, for example, wire-shaped or block-shaped, as long as they are energizable.

Furthermore, in the above embodiment, a pair of pillar parts 13A that support the end part of the second substrate 14 on the side where the Hall ICs 40 are arranged, but the number of these pillar parts 13A is not limited to two. The number of pillar parts 13A may be three or more, or may be one.

Moreover, in the above embodiment, the opening part 32a is provided to cover the second substrate 14, but the opening part 32a may be provided with an opening of a size that enables connection of the adjustment device for the current value conversion program.

Moreover, in the above embodiment, the circuit fixing parts 17Ab, 17Bb, 18Ab, 18Bb, 18Cb are fixed to the base member 20 by the bolts 52 that penetrate the first substrate 11 in the up-down direction, but the means for fixing the circuit fixing parts 17Ab, 17Bb, 18Ab, 18Bb, 18Cb is not limited to fastening by the bolts 52. The circuit fixing parts 17Ab, 17Bb, 18Ab, 18Bb, 18Cb may be fixed to the base member 20 by soldering.

What is claimed is:

1. A control device, comprising:
an energization busbar;
a substrate on which a controller is mounted;
a magnetic detection type current sensor that is mounted at a position close to the busbar on the substrate and that detects a magnetic field caused by current flowing through the busbar;
a case that accommodates the substrate and the busbar; and
a base member to which the case is fixed,
wherein the busbar is partially embedded and fixed in the case, and
the substrate is directly fixed to the base member.

2. The control device according to claim 1,
wherein the case comprises:
a case main body that has an opening part at a portion facing the substrate and that covers an installation part of the current sensor on the substrate and an outer side of the busbar; and
a cover part that is detachably mounted to the case main body so as to close the opening part.

3. The control device according to claim 1,
wherein the current sensor is provided to oppose the busbar, and
a portion of the busbar embedded and fixed in the case is arranged at a position close to the current sensor.

4. The control device according to claim 2,
wherein the current sensor is provided to oppose the busbar, and
a portion of the busbar embedded and fixed in the case is arranged at a position close to the current sensor.

5. The control device according to claim 1,
wherein the base member comprises a pillar part that protrudes in a direction of the substrate and to which the substrate is fixed,
a fixing part to which the pillar part is fixed is provided at an end part of the substrate in an extending direction, and
the current sensor is arranged in a vicinity of the fixing part.
